(19) United States
(12) Patent Application Publication
(10) Pub. No.: US 2026/0344055 A1
(43) Pub. Date: Oct. 29, 2026

(54) INTEGRATED CIRCUIT LAYOUT TO REDUCE ELECTROMAGNETIC INTERFERENCE

(71) Applicant: TEXAS INSTRUMENTS INCORPORATED, DALLAS, TX (US)

(72) Inventors: Markus ROMMEL, FREISING (DE); Juergen NEUHAEUSLER, ROSENHEIM (DE); Hermann MAYERHOFER, SCHWEITENKIRCHEN (DE); Xavier SCHERBAM, FREISING (DE)

(21) Appl. No.: 19/189,797

(22) Filed: Apr. 25, 2025

(51) Int. Cl. H10D 89/10; H02M 3/00; H05K 1/02; H05K 1/181; H10D 89/60

(52) U.S. Cl. CPC H10D 89/10; H02M 3/003; H05K 1/0215; H05K 1/181; H05K 2201/09227; H10D 89/811

(57) ABSTRACT

An example circuit can include a packaged integrated circuit (IC) having opposing first and second sides. The first side of the packaged IC can include a first ground terminal, a second ground terminal, and an input voltage terminal. The input voltage terminal can be located substantially equidistant between the first and second ground terminals along the first side of the packaged IC.

### TECHNICAL FIELD

This description relates to an integrated circuit layout to reduce electromagnetic interference.

### BACKGROUND

Power switches are used in a variety of applications to control the supply of electrical power. As an example, a controller can provide an input pulse-width modulated (PWM) signal to a driver circuit, which is configured to provide a drive signal to an output stage (e.g., one or more transistors). The output stage can include one or more transistors. In some circuit configurations, noise can be introduced at the input to the drive circuit, such as from parasitics or other sources, which can distort the input PWM signal. Such distortion can lead to corruption of the drive signal.

### SUMMARY

One described example relates to a circuit that includes a packaged integrated circuit (IC) having opposing first and second sides. The first side of the packaged IC can include a first ground terminal, a second ground terminal, and an input voltage terminal. The input voltage terminal can be located substantially equidistant between the first and second ground terminals along the first side of the packaged IC.

Another example relates to a circuit that includes a packaged integrated circuit (IC) including a package body having opposing first and second sides, and a converter circuit on a substrate in the package body. The first side of the package body can include a first ground terminal, a second ground terminal, and a first input voltage terminal. The first input voltage terminal can be located substantially equidistant between the first and second ground terminals along the first side of the package body. The second side of the package body can include a third ground terminal, a fourth ground terminal, and a second input voltage terminal. The second input voltage terminal can be located between the third and fourth ground terminals along the second side of the package body and the first ground terminal, second ground terminal, and first input voltage terminal are spatially symmetrical relative to the third ground terminals, the fourth ground terminal, and the second input voltage terminal, respectively. The converter circuit has first and second converter inputs and a converter output. The first converter input can be coupled to the first and second input voltage terminals, the second converter input is coupled to at least one of the first, second, third, or fourth ground terminals, and the converter output can be coupled to an output terminal along one side of the package body.

Another described example relates to a power converter circuit that includes a packaged IC and an arrangement of first, second, third, and fourth capacitors. The packaged integrated circuit (IC) includes a package body having opposing first and second sides. The packaged IC includes a first ground terminal, a second ground terminal, and a first input voltage terminal along the first side of the package body. The first input voltage terminal is located substantially equidistant between the first and second ground terminals. The packaged IC also includes a third ground terminal, a fourth ground terminal, and a second input voltage terminal along the second side of the package body. The second input voltage terminal is located substantially equidistant between the third and fourth ground terminals, and first input voltage terminal are spatially symmetrical relative to the third ground terminals, the fourth ground terminal, and the second input voltage terminal, respectively. The packaged IC can also include a bridge circuit on a substrate in the packaged IC, in which the bridge circuit includes a first supply input, a ground input, and an output. The first supply input can be coupled to the first and second input voltage terminals, and the ground input can be coupled to at least one of the first, second, third, or fourth ground terminals. The output of the bridge circuit can be coupled to an output terminal of the packaged IC along a respective side of the package body. The first capacitor has first and second terminals, in which the first terminal of the first capacitor is coupled to the first ground terminal and the second terminal of the first capacitor is coupled to the first input voltage terminal. The second capacitor has first and second terminals, in which the first terminal of the second capacitor is coupled to the second ground terminal and the second terminal of the second capacitor is coupled to the first input voltage terminal. The third capacitor has first and second terminals, in which the first terminal of the third capacitor is coupled to the third ground terminal and the second terminal of the third capacitor is coupled to the second input voltage terminal. The fourth capacitor has first and second terminals, in which the first terminal of the fourth capacitor is coupled to the fourth ground terminal and the second terminal of the fourth capacitor is coupled to the second input voltage terminal.

### BRIEF DESCRIPTION OF THE DRAWINGS

FIG. 1 is a circuit schematic and block diagram depicting an example circuit system configured to reduce electromagnetic interference.

FIG. 2 is a circuit schematic and block diagram depicting another example circuit system configured to reduce electromagnetic interference.

FIG. 3 is a plan view showing a schematic rendering of an example printed circuit board that includes circuitry configured to reduce electromagnetic interference.

FIG. 4 is a plan view showing a schematic rendering of another example printed circuit board that includes circuitry configured to reduce electromagnetic interference.

FIG. 5 is a plan view showing part of yet another example printed circuit board.

FIG. 6 depicts a packaged IC implemented in an example power converter circuit.

FIG. 7 depicts a packaged IC implemented in another example power converter circuit.

FIG. 8 is a diagram showing a comparison of input impedance over frequency.

### DETAILED DESCRIPTION

This description relates to circuits and systems configured to reduce electromagnetic interference, such as for power converter circuits.

Examples described herein include a packaged integrated circuit (IC) having opposing sides. As used herein, the packaged IC can refer to single-or multi-chip packages, system in a package (SIP), and/or a system on a chip (SOC). One or both sides of the packaged IC includes an arrangement of terminals (e.g., pins or pads of electrically conductive material, such as copper and/or alloys thereof) that spatially locate certain terminals relative to each other to reduce electromagnetic interference. For example, the first side of the packaged IC includes first and second ground terminals and an input voltage terminal. The voltage terminal is located substantially equidistant between the first and second ground terminals along a first side of the packaged IC to define what can be referred to as a single-butterfly layout. In other examples, which can be referred to herein as a double-butterfly layout, a second side of the packaged IC opposite the first side includes third and fourth second ground terminals and another input voltage terminal located substantially equidistant between the third and fourth ground terminals along the second side.

Both such configurations (e.g., the single-or double-butterfly layouts) can reduce (or cancel) the electromagnetic field across a horizontal axis of the packaged IC extending through the opposing first and second sides of the packaged IC. The double-butterfly layout can reduce (or cancel) the electromagnetic field across the horizontal axis of the packaged IC of the packaged IC as well as through a vertical axis that extends through the packaged IC orthogonally to the horizontal axis. For instance, electromagnetic interference related to the supply connection of the IC converter is further reduced.

In some examples, first and second input capacitors are placed on one or both first and second sides of the packaged IC. For example, the first input capacitor is coupled between the input terminal and the first ground terminal and the second input capacitor is coupled between the input terminal and the second ground terminal. This arrangement of capacitors can be referred to herein as a mirrored configuration, which can be configured with a lower parasitic inductance than existing approaches. The reduced parasitic inductance translates into a lower parasitic inductance of the input loop (e.g., supply voltage to ground) of the circuitry implementing the packaged IC (e.g., a power converter). The lower parasitic inductance can also enable internal switches (e.g., transistors) of the packaged IC to switch faster by allowing a higher dl/dt for a given induced voltage.

Additionally, in examples where the packaged IC and input capacitors having the single or double-butterfly layout is configured as a power converter (e.g., a DC-DC converter), the overall power (e.g., current) to the high-side and low-side power transistors can be directed in along parallel paths, which can reduce the overall input impedance because the resistive and capacitive input paths are bifurcated (e.g., split). This enables a more compact overall configuration for the supply voltage-to-ground system layout of the resulting circuit. The ground-supply voltage-ground configuration of the single and double-butterfly layouts described herein also can enable an effective use of 3-terminal capacitors as they can be directly coupled to the input pins of the IC to implement the first and second capacitors in the mirrored capacitor configuration along one or more sides of the packaged IC.

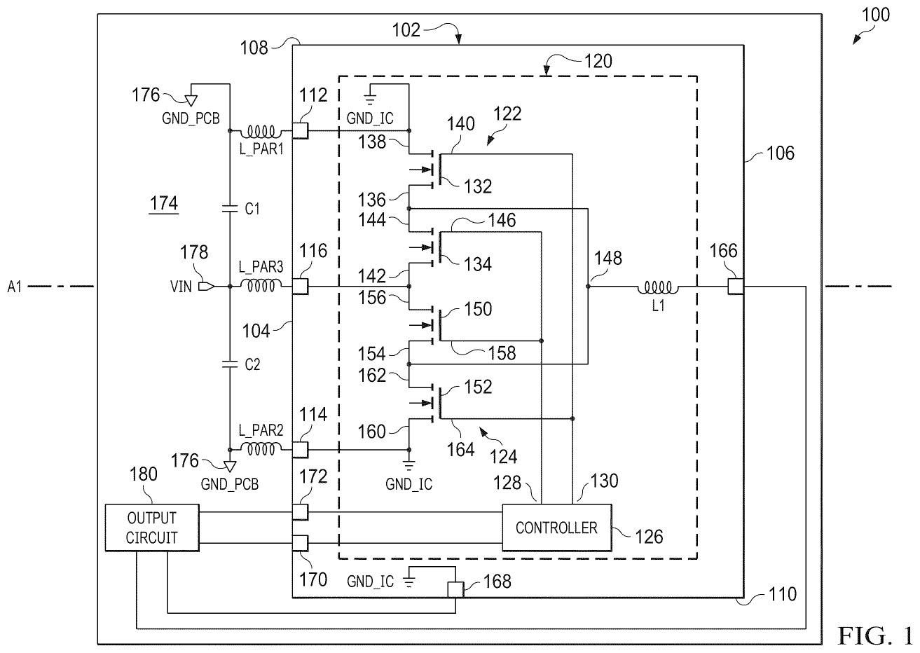

FIG. 1 is a circuit schematic and block diagram depicting an example circuit system 100. The system 100 includes a packaged IC 102 having opposing first and second sides 104 and 106, which are spaced apart from each other by another pair of opposing sides 108 and 110. The first side 104 of the packaged IC 102 includes a first ground terminal 112, a second ground terminal 114, and an input voltage terminal 116. In the example of FIG. 1, the input voltage terminal 116 is located substantially equidistant between the first and second ground terminals 112 and 114 along the side 104. In examples herein, each of the terminals of the packaged IC 102 can be implemented as a single pin or be grouped into blocks of pins for a respective connection (e.g., for the ground and/or voltage connections).

The packaged IC 102 includes one or more circuits 120 that can be formed on one or more substrates housed within the package body that defines the packaged IC. In some examples described herein, the one or more circuits 120 include a power converter circuit configured to convert a voltage at the input voltage terminal 116 to an output voltage that can be provided at an output terminal 166 of the packaged IC. The power converter can be a DC-DC buck, boost, buck-boost, or other converter topology. Also, or as an alternative, the one or more circuits 120 can include other types of circuits for performing other functions.

In the example of FIG. 1, the circuit 120 is depicted as a power converter that includes first and second half-bridge circuits 122 and 124 arranged in parallel. A controller 126 has outputs 128 and 130 coupled to respective inputs of each of the half bridge circuits 122 and 124. The half-bridge circuit 122 includes transistors (e.g., FETs, such as power FETs) 132 and 134 coupled in series between the first ground terminal 112 and the input voltage terminal 116. The transistor 132 includes a first current terminal 136 (e.g., a drain), a second current terminal 138 (e.g., source), and a control input 140 (e.g., gate), in which the first current terminal 136 is coupled to an output 148 (e.g., a switching node) of the circuit 120. The second current terminal 138 can be coupled to the first ground terminal 112, and the control input 140 can be coupled to the output 130 of the controller 126. The transistor 134 includes a first current terminal 142 (e.g., a drain), a second current terminal 144 (e.g., source), and a control input 146 (e.g., gate). The first current terminal 142 is coupled to input voltage terminal 116. The second current terminal 144 is coupled to the first current terminal 136 of transistor 132, which is also coupled to the output 148. The control input 140 is coupled to the output 128 of the controller 126.

The half-bridge circuit 124 includes transistors (e.g., FETs, such as power FETs) 150 and 152 coupled in series between the second ground terminal 114 and the input voltage terminal 116. The transistor 150 includes a first current terminal 154 (e.g., a drain), a second current terminal 156 (e.g., source), and a control input 158 (e.g., gate), in which the first current terminal 154 is coupled to the output 148, the second current terminal 156 is coupled to the input voltage terminal 116, and the control input 140 is coupled to the output 128 of the controller 126. The transistor 152 includes a first current terminal 160 (e.g., a drain), a second current terminal 162 (e.g., source), and a control input 164 (e.g., gate). The first current terminal 160 is coupled to the second ground terminal 114. The second current terminal 162 is coupled to the output 148, which is also coupled to the terminal 154 of the transistor 150. The control input 164 is coupled to the output 130 of the controller 126.

While the transistors 132, 134, 150, and 152 are shown as FETs in the example of FIG. 1, the transistors could be implemented in other examples as other types of transistors, such as a bipolar junction transistor (BJT), insulated-gate bipolar transistor (IGBT), laterally-diffused metal-oxide semiconductor (LDMOS) transistors, etc. For purposes of the example circuit system 100 of FIG. 1, the packaged IC 102 also includes an output terminal 166, shown on the side 106, another ground terminal 168 on the side 110, and sense terminals 170 and 172 on the same side 104 as terminals 112, 114, and 116. In other examples, the packaged IC can include other numbers and arrangements of terminals. Each of the ground terminals 112, 114, and 168 can be coupled to a ground terminal (e.g., a common IC ground) of the packaged IC 102.

The system 100 can be implemented on a printed circuit board (PCB—or other substrate), shown at 174, which includes an arrangement of circuit paths (e.g., electrically conductive traces, wires) and a circuit board ground 176 (e.g., a ground plane). The circuit board ground 176 can be coupled to the first and second ground terminals 112 and 114 through respective circuit paths (e.g., traces or wires), each having a respective parasitic inductance (L_PAR1 and L_PAR2). A voltage terminal 178 can also be coupled to the input voltage terminal 116 of the packaged IC 102 through a respective parasitic inductance (L_PAR3). The various parasitic inductances can be the same or different depending on the relative lengths and cross-sectional dimensions thereof. Also, each of the parasitic inductances L_PAR1, L_PAR2, and L_PAR3 can represent the sum of all parasitics between respective terminals of the capacitors C1 and C2 and power switches (or other circuitry coupled to the terminals) on the packaged IC 102, such as including the equivalent series inductance (ESL) of the capacitors, parasitic routing of the PCB connections, and the package inductances (e.g., bondwires and/or any routed package connections).

In the example of FIG. 1, the system 100 includes a first capacitor C1 coupled between the circuit board ground 176 and the voltage terminal 178. A second capacitor C2 is coupled between the second ground terminal 114 and the voltage terminal 178. For example, C1 and C2 define respective input capacitors, in which C1=C2. The voltage terminal 178 can be coupled to an output of a power supply (e.g., another power converter, such as a voltage regulator, a battery structure) to receive a DC voltage. The configuration of the system 100 shown on the PCB 174 in the example FIG. 1 can be considered a single-butterfly layout in that terminals 112 and 114 as well as the capacitors C1 and C2 are arranged symmetrically (e.g., in a mirrored construction) about a horizontal axis A1 extending through the input voltage terminal 116 and the sides 104 and 106 of the packaged IC 102. Such configuration can reduce (or cancel) electromagnetic field interference at the voltage inputs of the IC 102 (e.g., due to voltage supply connections) across the horizontal axis A1. Parasitic impedance at the input also can be reduced compared to many existing designs. The mirrored arrangement of capacitors C1 and C2 can further result in lower parasitic impedance. The reduced parasitic inductance can allow higher di/dt for a given induced voltage, which can further enable faster switching of switches (e.g., transistors) of the circuit 120.

The system 100 can also include an output circuit (e.g., load) 180, which can be implemented on the PCB 174 or external to the PCB through a respective connection. The output circuit includes inputs coupled to the ground terminal 168 and the output terminal 166. The output circuit 180 can also be coupled to terminals 170 and 172, such as to provide feedback representative of operating parameters (e.g., voltage, current, etc.) to the controller 126. An inductor L1 can be coupled between the output 148 of the circuit 120 and the output circuit 180. The inductor L1 can be implemented on the packaged IC 102, such as coupled between the output 148 of the circuit 120 and the output terminal 166 (as shown) or the inductor L1 can be external to the packaged IC. In an example, a sensed voltage of the output circuit 180 is provided at the terminals 170 and 172. The controller 126 can be configured to control the circuit 120 responsive to the feedback signals provided at the terminals 170 and 172. For example, the controller is configured to control the circuit 120, such as by providing control signals at outputs 128 and 130 to the respective control inputs 140, 146, 158, and 164, responsive to the feedback signals received at the terminals 170 and 172 from the output circuit 180.

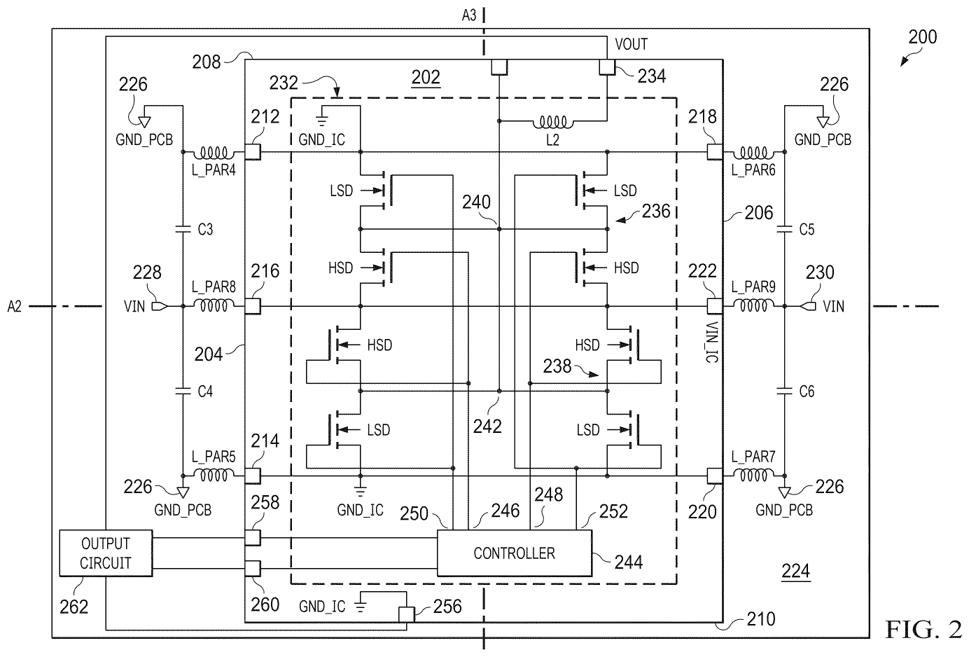

FIG. 2 is a circuit schematic and block diagram depicting another example circuit system 200. The circuit system of FIG. 2 is an alternative layout that can be implemented to further reduce electromagnetic interference. Whereas the layout in the example system of FIG. 1 has symmetry about a horizontal axis A1, the example system 200 of FIG. 2 has a layout that exhibits symmetry about the horizontal axis A2 of the packaged IC as well as about a vertical axis A3 that extends through the packaged IC orthogonally to the horizontal axis A2. The layout shown in the example of FIG. 2 can be referred to herein as a double-butterfly layout when compared to the single-butterfly layout of FIG. 1.

The circuit system 200 includes a packaged IC 202, which defines a package body, having first and second opposing sides 204 and 206 that are spaced apart from each other by third and fourth opposing sides 208 and 210. In the example orientation shown FIG. 2, an axis A2 extends through the sides 204 and 206 and another axis A3, which can be orthogonal and coplanar with axis A2, extends through the other sides 208 and 210. The packaged IC 202 includes a first ground terminal 212, a second ground terminal 214, and a first input voltage terminal 216 along the first side 204. The packaged IC 202 also includes a third ground terminal 218, a fourth ground terminal 220, and a second input voltage terminal 222 along the second side 206 of the package body. The voltage terminal 216 can be located substantially equidistant between the ground terminals 212 and 214, and the voltage terminal 222 can be substantially equidistant between the ground terminals 218 and 220 along their respective sides. As shown in the example of FIG. 2, the circuit system 200 includes a PCB 224 having a surface on which the packaged IC 202 and other circuitry is mounted.

The PCB 224 includes an arrangement of circuit paths (e.g., electrically conductive traces, wires) and a circuit board ground 226 (e.g., a ground plane). The circuit board ground 226 can be coupled to the ground terminals 212, 214, 218, and 220 through respective circuit paths (e.g., traces or wires), each having a respective parasitic inductance, shown as L_PAR4 and L_PAR5, L_PAR6, and L_PAR7. Voltage terminals 228 and 230 can also be coupled to respective input voltage terminals 216 and 222 through respective parasitic inductances L_PAR8 and L_PAR9. While shown as separate terminals 228 and 230, such terminals can be implemented as a common coupling to an input voltage source (not shown), which may be on the PCB 224 or implemented externally to the PCB. The various parasitic inductances can be the same or different and can represent the sum of associated parasitic inductances associated with each respective circuit path (e.g., traces, ESL of the capacitors, parasitic routing of the PCB connections, and package inductances).

In the example of FIG. 2, the circuit system 200 also includes input capacitors C3, C4, C5, and C6. C3 is coupled between the ground terminal 212 and the voltage terminal 216, such that the paths between terminals of C3 and associated circuitry in the IC 202 include a respective parasitic inductance L_PAR4 and L_PAR8. C4 is coupled between the ground terminal 214 and the voltage terminal 216, such that the paths between terminals of C4 and associated circuitry in the IC 202 includes a respective parasitic inductance L_PAR5 and L_PAR8. On the other side of the package body, C5 is coupled between the ground terminal 218 and the voltage terminal 222 and C6 is coupled between the ground terminal 220 and the voltage terminal 222. The paths between terminals of each of C5 and C6 and associated circuitry in the IC 202 further includes respective parasitic inductance represented as L_PAR4, L_PAR5, and L_PAR9. In some examples, the capacitors C3 and C4 are implemented by a three-terminal capacitor and/or the capacitors C5 and C6 are implemented by another three-terminal capacitor.

The packaged IC 202 includes one or more circuits 232 that can be formed on one or more substrates housed within the package body that defines the packaged IC. In some examples described herein, the one or more circuits 232 include power converter circuitry configured to convert a voltage at the input voltage terminals 228 and 230 to an output voltage at an output terminal 234 of the packaged IC 202. In the example of FIG. 2, the output terminal is on the side 208 but could be provided at one or more other sides 204, 208, 210, and 212 of the packaged IC in other examples. The power converter can be a DC-DC buck, boost, buck-boost, or other converter topology. Also, or as an alternative, the one or more circuits 232 can include other types of circuits for performing other functions.

In the example of FIG. 2, the circuit 232 is depicted as a power converter that includes first and second bridge circuits 236 and 238 arranged in parallel between input voltage terminals 216, 222 and the output terminal 234. Each of the bridge circuits 236 and 238 can be considered as having two half-bridge circuits, each of which half-bridge circuits can be configured similarly to as described with respect to the half bridge circuits of FIG. 1. Thus, each bridge circuit 236 and 238 can include an arrangement of transistors (e.g., FETs, such as power FETs) coupled between respective terminals of the packaged IC 202, such as shown in FIG. 2. As a further example, the packaged IC can include internal electrical connections (e.g., on-die routing and/or bondwires) configured to electrically couple the voltage terminal 216 to the terminal 222, to electrically couple the terminal 212 to the terminal 218, and to electrically couple the terminal 214 to the terminal 220. In the double-butterfly example of FIG. 2, each of the bridge circuits 236 and 238 is configured as a respective full bridge circuit, in which each bridge circuit includes a respective switching output terminal (e.g., switching node) 240 and 242 that is coupled to the output terminal 234.

A controller 244 has outputs 246, 248, 250, and 252 coupled to respective control inputs (e.g., to gates of respective transistors) of each of the bridge circuits 236 and 238. In the example of FIG. 2, the output 246 is coupled to control inputs of a first pair of high-side transistors in each of the bridge circuits 236 and 238 and the output 248 is coupled to control inputs of another pair of high-side transistors of the bridge circuits. The other outputs 250 and 252 are each coupled to respective pairs of low-side transistors in each of the bridge circuits 236 and 238. In other examples, separate controller outputs can be coupled to control inputs (e.g., gates) of each of the respective transistors in the circuit 232 to enable independent control thereof.

In the example shown in FIG. 2, the packaged IC 202 also includes another ground terminal 256 on the side 210, and sense terminals 258 and 260 on the same side 204 as terminals 212, 214, and 216. In other examples, the packaged IC 202 can include other numbers and/or arrangements of terminals. Each of the ground terminals 212, 214, 218, 220 and 256 can be coupled to a ground terminal (e.g., a common IC ground) of the packaged IC 202. The system 200 can also include an output circuit (e.g., including an output capacitor and/or load) 262, which can be implemented on the PCB 224 or external to the PCB through one or more respective connections. The output circuit 262 includes inputs coupled to the ground terminal 256 and the output terminal 234. The output circuit 262 can also be coupled to terminals 258 and 260, such as to provide feedback representative of operating parameters (e.g., voltage, current, etc.) to respective inputs of the controller 244. An inductor L2 can be coupled between the output 148 of the circuit 232 and the output circuit 180. The inductor L1 can be implemented on the packaged IC 102, such as coupled between the output 240, 242 of the circuit 232 and the output terminal 234 (as shown) or, in other examples, the inductor L2 can be external to the packaged IC. In an example, a sensed voltage potential of the output circuit 262 is provided at the terminals 258 and 260. The controller 244 can be configured to control the circuit 232 responsive to the feedback signals provided at the terminals 258 and 260. For example, the controller 244 is configured to control the circuit 232, such as by providing control signals (e.g., pulsed signals) at outputs 246, 248, 250, and 252 to the respective control inputs of the bridge circuits 236 and 238, responsive to the feedback signals received at the terminals 258 and 260 from the output circuit 180. Advantageously, because the electromagnetic interference along both sides 204 and 206 of the packaged IC is reduced (or cancelled) because of the double-butterfly arrangement of terminals and circuitry, the input signals recited at the terminals 258 and 260 can be more accurate of the measured signals. As a result, the controller 244 can operate the circuit 232 at faster switching rates and improved performance compared to many existing approaches.

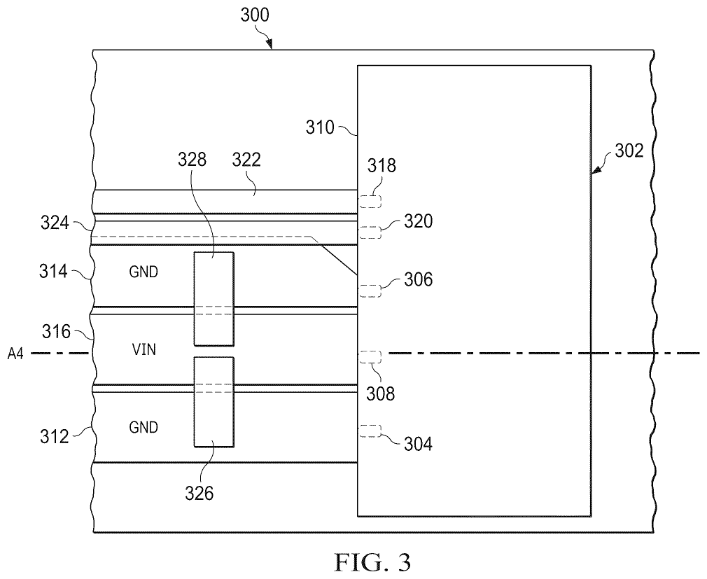

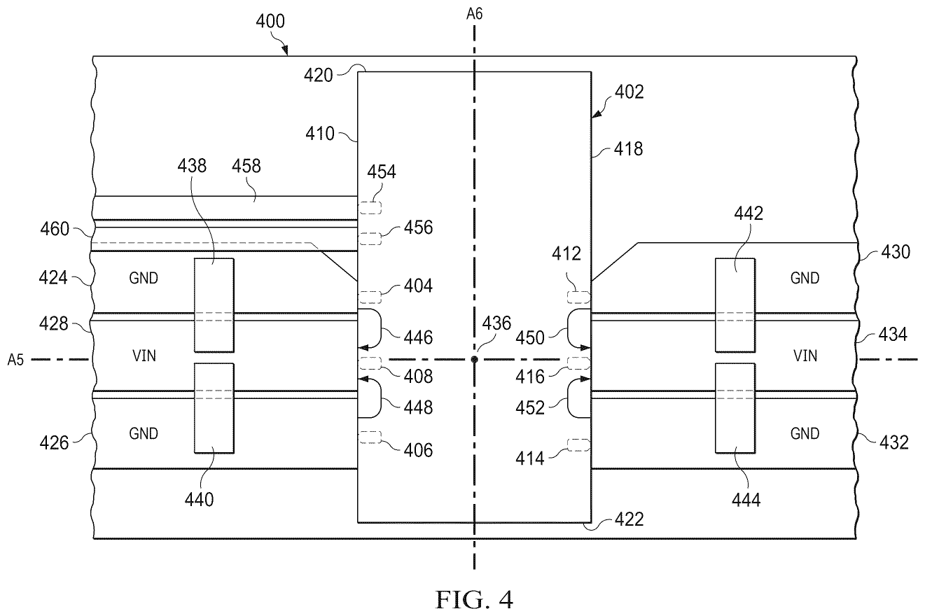

FIGS. 3 and 4 are plan views showing a schematic rendering of portions of example PCBs that include circuitry configured to reduce electromagnetic interference. FIG. 3 depicts a portion of a PCB 300 for an example single-butterfly layout similar to the example of FIG. 1. Accordingly, the description of FIG. 3 can also refer to certain aspects of FIG. 1. The PCB 300 of FIG. 3 includes packaged IC 302 mounted on a surface of the PCB. The packaged IC 302 includes ground terminals 304 and 306 and an input terminal 308 along a respective side 310 of the IC. The input terminal 308 is located approximately midway between the ground terminals 304 and 306. A respective trace (or other form of connection) 312 and 314 of the PCB 300 can be coupled to and extend away from each ground terminal 304 and 306. A voltage trace (or other form of connection) 316 can be coupled to the input terminal 308. The trace 316 can extend along or within the PCB 300 away from the input terminal 308 substantially parallel to and spaced intermediate the traces 312 and 314 (also extending way from respective terminals), which provides a ground-supply voltage-ground configuration along the side 310.

An axis (e.g., a horizontal axis) A4 extends through the input terminal 308 and the trace 316, which demonstrates a line of symmetry around the input voltage path for the ground-supply voltage-ground configuration. The PCB also includes capacitors 326 and 328, in which the capacitor is coupled between the trace 312 (which is coupled to ground terminal 304) and input trace 316 (which is coupled to terminal 308) and the capacitor 328 is coupled between the ground trace 314 (which is coupled to ground terminal 306) and input trace 316 (which is coupled to terminal 308) on each side of the axis A4. The capacitors further can be implemented by a single three-terminal capacitor.

The ground-supply voltage-ground configuration along the side 310 thus provides parallel paths for current to the circuitry of the packaged IC 302, such electromagnetic interference due to signals (e.g., current) through the parasitic inductances along each parallel path can reduce or cancel out electromagnetic interference of the other path. Moreover, by reducing electromagnetic interference the ground-supply voltage-ground configuration enables a more compact configuration. For example, the packaged IC includes terminals 318 and 320, which are located along the same side 310 and in close proximity to the terminal 306. In other examples, the terminals 318 and 320 could be located in close proximity (e.g., below) to the other ground terminal 304 (see, e.g., FIG. 1). The PCB includes respective traces (or other forms of connections) 322 and 324 that are coupled to the terminals 318 and 320. Because the ground-supply voltage-ground configuration reduces interference the information (e.g., signal measurements) provided at terminals 318 and 320 through traces 322 and 324, respectively, can have increased accuracy than many existing systems even in the compact design shown in FIG. 3.

The example of FIG. 4 depicts a portion of a circuit system on a PCB 400 for an example double-butterfly layout similar to the example of FIG. 2. Accordingly, the description of FIG. 4 can also refer to certain aspects of FIG. 2. The PCB 400 of FIG. 4 includes packaged IC 402 mounted on a surface of the PCB. The packaged IC 402 includes ground terminals 404 and 406 and an input terminal 408 along a respective side 410 of the IC. The input terminal 408 is located approximately midway between the ground terminals 404 and 406 on the side 410. In the double-butterfly-layout of FIG. 4, the packaged IC 402 also includes ground terminals 412 and 414 and another input terminal 416 along another side 418 opposite the side 410. The input terminal 416 is located approximately midway between the ground terminals 412 and 414 on the side 418. Thus, the ground and input terminals 404-408 and 412-416 along each respective side 410 and 418 of the packaged IC have a ground-voltage supply-ground configuration. As a further example, an axis (e.g., a horizontal axis) A5 extends through the input terminals 408 and 416 the traces 428 and 434, which demonstrates a first line of symmetry for an input voltage path at each opposing side of the packaged IC 402. Another axis (e.g., a vertical axis) A6 extends through the opposing sides 420 and 422 of the packaged IC 402, such as midway between opposing sides 410 and 418, which further can be orthogonal and coplanar with axis A5. An intersection between axes A5 and A6, shown at 436, can define a central point of symmetry for the packaged IC 402. The double-butterfly configuration of the circuitry on the PCB 400 thus has multi-dimensional symmetry about the central point of symmetry 436.

As shown in the example of FIG. 4, traces 424, 426, 428, 430, 432, and 434 are coupled to each of the respective terminals 404, 406, 408, 412, 414, and 416. Each of the traces 424, 426, and 428 (e.g., defining a first set of traces) can extend outwardly and away from the side 410 and traces 430, 432, and 434 (e.g., defining a second set of traces) can extend outwardly and away from the other side 418. The traces 424, 426, and 428 in the first set of traces can be arranged parallel to each other, at least along a portion thereof that couples to the terminals 404, 406, and 408. Similarly, the traces 430, 432, and 434 in the second set of traces can be arranged parallel to each other, at least along a portion thereof that couples to the terminals 412, 414, and 416. The traces 424, 426, 430, and 432 can define respective ground connections and the traces 428 and 434 can define respective input voltage traces, providing respective parallel input connections having ground-supply voltage-ground configurations along each side of the packaged IC 402. In addition to the symmetry of the ground-supply voltage-ground configurations along each respective side of the packaged IC 402, the double-butterfly configuration also exhibits symmetry between the sides of the package body along the axis A6.

The PCB 400 can also include a first pair of capacitors 438 and 440 coupled to input connection traces 424, 426, and 428 at the side 410 and a second pair of capacitors 442 and 444 coupled to input connection traces 430, 432, and 434 at the opposite side 418. In some examples, the capacitors 438 and 442 can be located symmetrically on opposite sides of the axis A5 relative to the respective capacitors 440 and 444.

As described herein, the double-butterfly layout that includes ground-supply voltage-ground input connections along opposite sides 410 and 418 of the packaged IC 402 provides parallel paths for input current to each side of the packaged IC. Electromagnetic interference, shown schematically by arrows 446 and 448, which is induced by current signals through parasitic inductances along the ground-supply voltage-ground input connection at the side 410 of the packaged IC can reduce (or cancel out) each other. The electromagnetic interference, shown schematically by arrows 450 and 452, which is induced by current signals through parasitic inductances of the along the ground-supply voltage-ground input connection at the side 420 of the packaged IC likewise can reduce (or cancel out) each other. Additionally, by reducing electromagnetic interference the ground-supply voltage-ground connections on one or both sides 410 and 418 can enable a more compact circuit configuration.

In the example of FIG. 4, the packaged IC 402 includes terminals 454 and 456, which are located along the same side 410 and in close proximity to the terminal 404. The PCB 400 includes respective traces (or other forms of connections) 458 and 460 that are coupled to the terminals 454 and 456. In other examples, the terminals 454 and 456 could be located adjacent (e.g., below or directly below) to the other ground terminal 304 on the side 410 (see, e.g., FIG. 2). Also, or alternatively, terminals (not shown) could be similarly located above or below (e.g., in close proximity to) the terminals 412 or 414 on the other side 418 of the packaged IC 402. Because of the ground-supply voltage-ground connections on both sides, electromagnetic interference is reduced so that terminals carrying sensitive information can be closer to the terminals 404, 406, 408, 412, 414, and 416 than in many existing configurations.

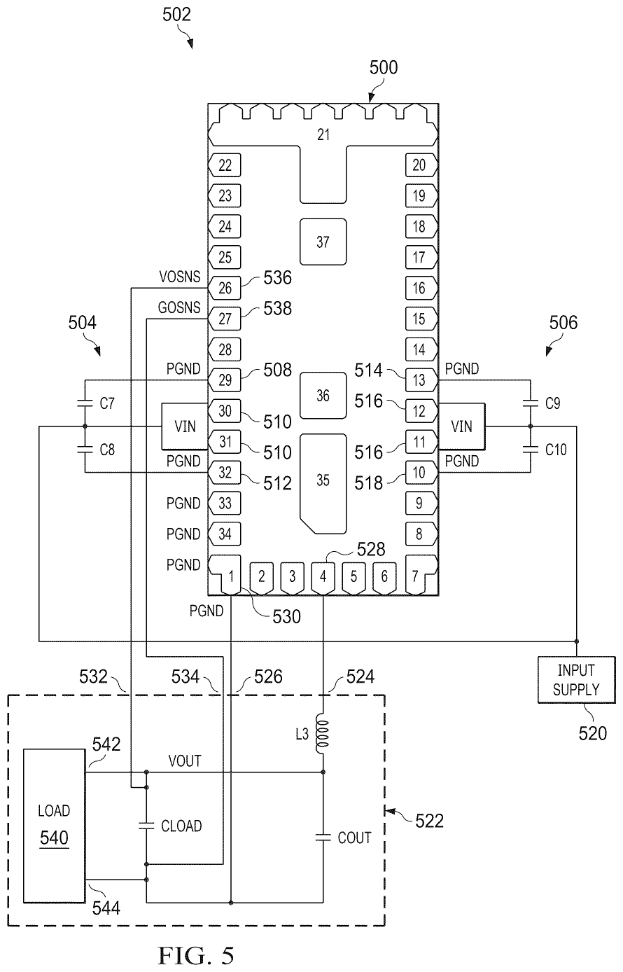

FIG. 5 depicts an example of a packaged IC 500 implemented in a circuit 502, such as a power converter circuit. In the example of FIG. 5, the packaged IC 500 includes a pinout that includes an arrangement of pins or pads (e.g., numbered 1 through 34) along an inner periphery of the package body at or adjacent the side edges of the package body. The packaged IC 500 also includes an arrangement of thermal pads (e.g., numbered 35 through 37) distributed along a central portion of the package body. The pins and pads can be exposed on a bottom side (and/or sidewalls) of the packaged IC 500 for contacting corresponding pads of a PCB (not shown).

In the example of FIG. 5, the circuit 502 includes a double-butterfly configuration having ground-supply voltage-ground input connections 504 and 506 along opposite sides of the packaged IC 500. The double-butterfly configuration can be implemented according to the examples described herein, including FIGS. 2 and 4. Accordingly, the description of FIG. 5 can refer to FIGS. 2 and/or 4. Briefly stated, an input capacitor C7 is coupled between a ground terminal 508 (e.g., numbered pin 29) and an input voltage terminal 510 (e.g., numbered pins 30 and 31) and another input capacitor C8 is coupled between another ground terminal 512 (e.g., numbered pin 32) and the input voltage terminal 510 to define the ground-supply voltage-ground input connection 504. The other ground-supply voltage-ground input connection 506 includes an input capacitor C9 coupled between a ground terminal 514 (e.g., numbered pin 13) and an input voltage terminal 516 (e.g., numbered pins 12 and 11) and another input capacitor C10 coupled between another ground terminal 518 (e.g., numbered pin 10) and the input voltage terminal 516. In some examples, the input terminals can be a single conductive block. Each of the pins can be a single pin or be grouped into blocks of pins for a respective connection (e.g., for the ground and/or input voltage connections).

The circuit 502 also includes an input supply 520 having an output coupled to each of the input voltage terminals 510 and 516, which is also coupled to the intermediate node between each respective pair of capacitors C7-C8 and C9-C10. The input supply 520 can be a DC-DC converter, and AC-DC converter, or other power supply configured to provide a DC input voltage to the input voltage terminals 510 and 516 of the packaged IC 500. Other types of input supplies can be used in other examples.

The circuit 502 also includes an output circuit 522 having inputs 524 and 526 coupled to respective terminals 528 and 530 of the packaged IC 500. In an example, the terminal 528 is an output terminal that can be coupled to an output of one or more bridge circuits (e.g., switching node output 148, 240, 242). The terminal 530 is a ground of the packaged IC 500 (e.g., a power ground terminal (PGND)), which can be coupled to ground terminals 508, 512, 514, and 518 through internal routing of the IC. The output circuit 522 can also have outputs 532 and 534 coupled to respective terminals 536 and 538 of the packaged IC 500. The output circuit can also include an inductor L3, an output capacitor COUT, and a load 540. The load can include a load capacitance (e.g., intrinsic to the load), represented as CLOAD across first and second load inputs 542 and 544. In the example of FIG. 5, the inductor L3 is external to the packaged IC 500 and coupled between the terminal 528 and the first load input 542. The output capacitor COUT is coupled between the load inputs 542 and 544 in parallel with the load capacitance CLOAD.

The circuitry of the packaged IC 500 can be configured to provide an output voltage VOUT across the load inputs 542 and 544. For example, the terminals 536 and 538 of the packaged IC 500 are implemented as sense terminals configured to receive signals (e.g., a voltage potential) representative of V OUT that is received at the load 540, such as to provide feedback for controlling the circuitry (e.g., circuit 120, 232) of the packaged IC 500. As described herein, the ground-supply voltage-ground input connection 504 results in reduced electromagnetic interference and lower impedance (e.g., lower parasitic inductances). As a result of the reduced interference, the feedback signals at terminals 536 and 538 can provide more accurate representation of the signal measurements (e.g., VOUT). Additionally, the reduced impedance allows a greater di/dt at the input voltage, which further can enable faster switching within the packaged IC.

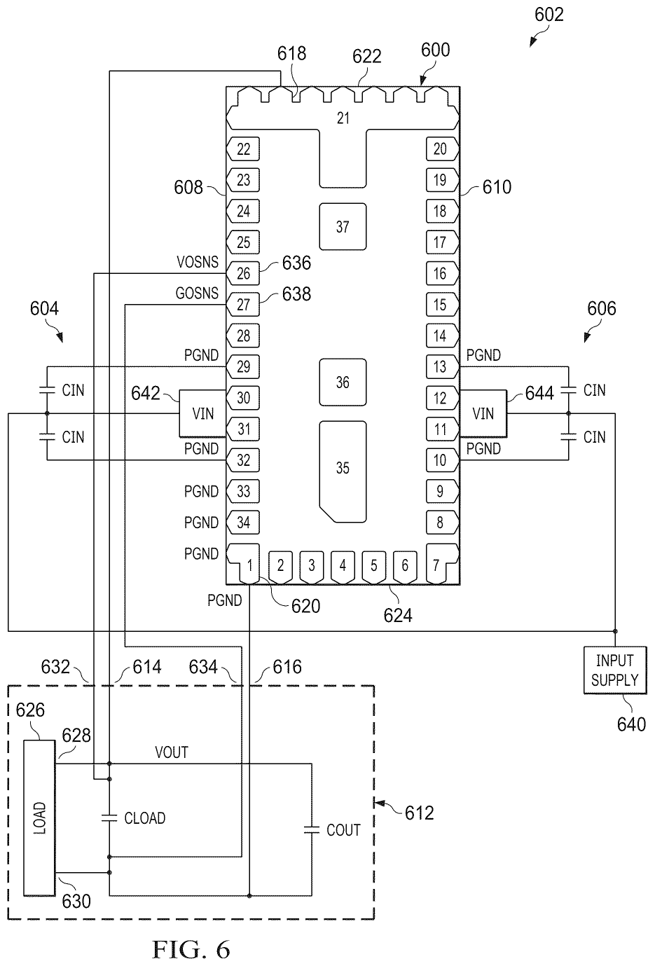

FIG. 6 depicts another example of a packaged IC 600 implemented in a circuit 602, such as a power converter circuit. The circuit 602 includes substantially identical ground-supply voltage-ground input connections 604 and 606 along opposite sides 608 and 610 of the packaged IC 600 as the circuit 502 of FIG. 5. The example of FIG. 6 differs from power converter circuit of FIG. 5 in that the inductor L3 is implemented internally (not externally) to the packaged IC 600 (see, e.g., inductor L2 of FIG. 2) and, as a result of including such internal inductor, an output circuit 612 can be coupled to the IC differently.

For example, the output circuit 612 has inputs 614 and 616 coupled to respective terminals 618 and 620 the packaged IC 600. In the example of FIG. 6, the terminals 618 and 620 are on opposing sides 622 and 624 of the packaged IC 600 (e.g., top and bottom sides). In other examples, each of the terminals can be located any of the sides 608, 610, 622, and 624, including on the same or different sides thereof the package body.

In a first example, the packaged IC 600 includes an internal inductor that is implemented on the same die as power converter circuitry that includes one or more bridge circuits (see, e.g., FIG. 1 or 2), in which the inductor is coupled between the terminal 618 and an output switching terminal (e.g., switching node output 148, 240, 242) of the one or more bridge circuits. In a second example, the internal inductor can be implemented within the packaged IC externally to the die containing power converter circuitry, such as coupled between an output switching terminal of the die (or another packaged IC) and the terminal 618 of the packaged IC (e.g., an SOC). In each of the first and second examples, the output terminal 618 can define an output voltage terminal (e.g., shown as number pad 21), such as to provide an output voltage VOUT. The output terminal 620 can be a power ground terminal (e.g., PGND) of the packaged IC 600, which can be coupled (e.g., through internal routing of the packaged IC) to other ground terminals of the IC.

The output circuit 612 can also include a load 626 having load inputs 628 and 630. The load 626 can include a load capacitance (e.g., intrinsic to the load), represented as CLOAD across first and second load inputs 628 and 630. An output capacitor COUT is coupled between the load inputs 628 and 630 in parallel with the load capacitance CLOAD, which are further coupled to (or define) respective inputs 614 and 616 of the output circuit 612. The output circuit 612 can also include outputs 632 and 634 that are coupled to respective terminals 636 and 638 of the packaged IC 600.

The circuit 602 can also include an input supply 640 having an output coupled to respective input voltage terminals 642 and 644, which is also coupled to the intermediate node between each respective pair of input capacitors. The input supply 640 can be a DC-DC converter, and AC-DC converter, or other power supply such as described herein.

As a further example, the power converter circuitry of the packaged IC 600 can be configured to provide an output voltage V OUT across the load inputs 628 and 630. The terminals 636 and 638 of the packaged IC 600 can be implemented as sense terminals configured to receive signals (e.g., a voltage potential) representative of VOUT that is received at the load 626, such as to provide feedback for controlling the circuitry (e.g., circuit 120, 232) of the packaged IC 600 during operation. As described herein, the ground-supply voltage-ground input connections 604 and 606 at opposing sides 608 and 610 results in reduced electromagnetic interference and lower impedance (e.g., lower parasitic inductances). As a result of the reduced interference, the feedback signals at terminals 636 and 638 can provide more accurate representation of the signal measurements (e.g., VOUT). Additionally, the reduced impedance at the input paths allows a higher di/dt at the input voltage, which further can enable faster switching within the packaged IC.

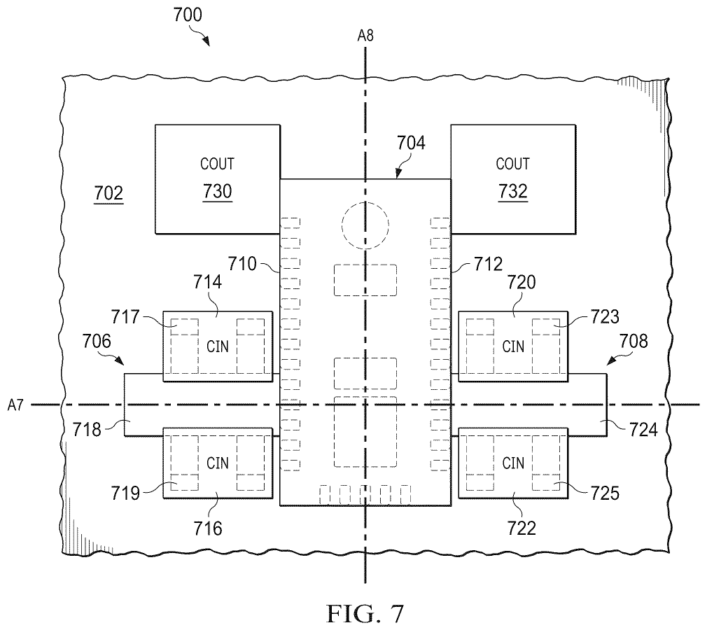

FIG. 7 is a plan view showing part of another example circuit 700 (or at least a portion thereof) implemented on a PCB 702. The circuit 700 has a double-butterfly configuration and thus provides a further example of the circuits of FIGS. 2, 4, 5, and 6. Accordingly, the description of FIG. 7 can also refer to certain aspects of FIGS. 2, 4, 5, and 6.

The circuit 700 includes a packaged IC 704 mounted to a surface of the PCB and respective ground-supply voltage-ground input connections 706 and 708 along opposite sides 710 and 712 of the packaged IC 704. The packaged IC 704 can include power converter circuitry and/or other types of circuitry that receives an input voltage VIN from a power supply that may reside on the PCB or be coupled to the PCB through one or more connections. Each of the ground-supply voltage-ground input connections 706 and 708 can be symmetric to each other about orthogonal axes A7 and A8. For example, ground-supply voltage-ground input connection 706 includes a pair of input capacitors 714 and 716 (e.g., capacitors 438, 440, C7, C8), in which the capacitor 714 is coupled between a first ground terminal 717, shown beneath the capacitor, and a voltage input trace 718. The other capacitor 716 is coupled between a second ground terminal 719, shown beneath capacitor 716, and the voltage input trace 716. The other ground-supply voltage-ground input connection 708 includes a pair of input capacitors 720 and 722 (e.g., capacitors 442, 444, C9, C10). The capacitor 720 is coupled between a 720, shown beneath capacitor, and a voltage input trace 724. The capacitor 722 is coupled between a second ground 725, shown beneath capacitor 722, and the voltage input trace 724. Each of the respective terminals and traces 717, 718, 719, 723, 724, and 725 can be coupled to respective pins (or pads) of the packaged IC through traces and/or other conductive elements routed through one or more layers of the PCB 702.

In the example of FIG. 7, the circuit also includes respective output capacitors (e.g., COUT of FIGS. 5 and 6) 730 and 732. The output capacitors 730 and 732 can be coupled across inputs to which one or more loads is adapted to be coupled (not shown-see, e.g., loads 540 and 626 and associated connections in FIGS. 5 and 6).

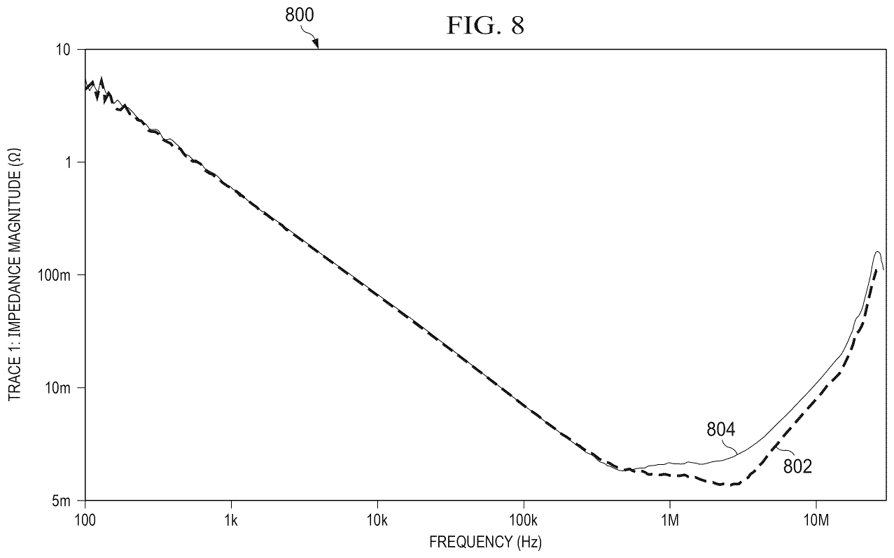

FIG. 8 is a diagram 800 showing plots 802 and 804 of input impedance over frequency for two different power converter circuits. The plot 802 demonstrates impedance for a power circuit having a ground-supply voltage-ground layout in a double-butterfly configuration, as described herein (e.g., FIGS. 2, 4, 5, 6). The other plot 804 is for an existing design that does not include the ground-supply voltage-ground layout in a single or double butterfly configuration. A comparison of the plots demonstrates a reduced input impedance for the circuits and systems described herein compared to an existing design. The resulting reduced impedance enables a more compact system layout. The symmetry in the ground-supply voltage-ground layout further can reduce (or cancel) electromagnetic interference along each side of the IC as well as between opposing sides. Y et a further benefit of such configuration is lower parasitic inductance, which can allow a higher di/dt at the voltage input to enable faster transistor switching compared to the existing approach.

In this description, numerical designations “first”, “second”, etc. are not necessarily consistent with same designations in the claims herein. Spatially relative terms, such as “top,” “bottom,” “above,” “below,” “beneath”, “proximate”, “distal”, and the like, may be used herein for ease of description to describe one element or feature's relationship to another element(s) or feature(s) as illustrated in the figures. It will be understood that the spatially relative terms can encompass different orientations of a device in use or operation, in addition to the orientation depicted in the figures. For example, if a device in the figures is inverted, elements described as “beneath” other elements or features would then be oriented “over” the other elements or features.

Additionally, the term “couple” may cover connections, communications, or signal paths that enable a functional relationship consistent with this description. For example, if device A generates a signal to control device B to perform an action, then: (a) in a first example, device A is directly coupled to device B ; or (b) in a second example, device A is indirectly coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Modifications are possible in the described embodiments, and other embodiments are possible, within the scope of the claims.

What is claimed is:

1. A circuit comprising:
a packaged integrated circuit (IC) having opposing first and second sides,
wherein the first side of the packaged IC includes a first ground terminal, a second ground terminal, and an input voltage terminal, in which the input voltage terminal is located substantially equidistant between the first and second ground terminals along the first side of the packaged IC.

2. The circuit of claim 1, further comprising:
a printed circuit board (PCB) having a surface, in which the packaged IC is mounted to the surface of the PCB, the PCB comprising:
a first trace having a proximal end coupled to the first ground terminal and extending from the proximal end thereof away from the packaged IC;
a second trace having a proximal end coupled to the second ground terminal and extending from the proximal end thereof away from the packaged IC; and
a third trace having a proximal end coupled to the input voltage terminal and extending from the proximal end thereof away from the packaged IC;
a first capacitor coupled between the first ground terminal and the input voltage terminal; and
a second capacitor coupled between the second ground terminal and the input voltage terminal.

3. The circuit of claim 1, wherein:
the input voltage terminal is a first input voltage terminal,
the second side of the packaged IC includes a third ground terminal, a fourth ground terminal, and a second input voltage terminal,
the second input voltage terminal is located between the third and fourth ground terminals along the second side of the packaged IC, and
the first ground terminal, the second ground terminal, and first input voltage terminal are arranged spatially symmetrically relative to the third ground terminal, the fourth ground terminal, and the second input voltage terminal, respectively.

4. The circuit of claim 3, further comprising:
a printed circuit board (PCB ) having a surface, in which the packaged IC is mounted to the surface of the PCB, the PCB comprising:
a first trace having a proximal end coupled to the first ground terminal and extending from the proximal end thereof away from the packaged IC;
a second trace having a proximal end coupled to the second ground terminal and extending from the proximal end thereof away from the packaged IC;
a third trace having a proximal end coupled to the third ground terminal and extending from the proximal end thereof away from the packaged IC; and
a fourth trace having a proximal end coupled to the fourth ground terminal and extending from the proximal end thereof away from the packaged IC.

5. The circuit of claim 4, wherein the PCB further comprises:
a fifth trace having a proximal end coupled to the first input voltage terminal and extending from the proximal end thereof away from the packaged IC; and
a sixth trace having a proximal end coupled to the second input voltage terminal and extending from the proximal end thereof away from the packaged IC.

6. The circuit of claim 5, wherein:
at least a proximal end portion of the fifth trace extends longitudinally between respective proximal end portions of the first trace and the second trace, and
at least a proximal end portion of the sixth trace extends longitudinally between respective proximal end portions of the third trace and the fourth trace.

7. The circuit of claim 6, further comprising
a first capacitor having first and second terminals, in which the first terminal of the first capacitor is coupled to the proximal end portion of the first trace, and the second terminal of the first capacitor is coupled to the proximal end portion of the fifth trace;
a second capacitor having first and second terminals, in which the first terminal of the second capacitor is coupled to the proximal end portion of the second trace, and the second terminal of the second capacitor is coupled to the proximal end portion of the fifth trace;
a third capacitor having first and second terminals, in which the first terminal of the third capacitor is coupled to the proximal end portion of the third trace, and the second terminal of the third capacitor is coupled to the proximal end portion of the sixth trace; and
a fourth capacitor having first and second terminals, in which the first terminal of the fourth capacitor is coupled to the proximal end portion of the fourth trace, and the second terminal of the fourth capacitor is coupled to the proximal end portion of the sixth trace.

8. The circuit of claim 7, wherein:
the IC package has opposing third and fourth sides that extend between the first and second sides,
the IC package has a first axis extending through the first and second sides and through the fifth and sixth traces,
the IC package has a second axis extending through the third and fourth sides at an intermediate location between the first and second sides, in which the first axis and the second axis are orthogonal with respect to each other, and
the first and second capacitors and the third and fourth capacitors are arranged on the PCB symmetrically with respect to the first axis and the second axis.

9. The circuit of claim 7, wherein:
the first capacitor and the second capacitor define a first three-terminal capacitor, in which the second terminal of the first capacitor and the second terminal of the second capacitor are the same terminal of the first three-terminal capacitor, and
the third capacitor and the fourth capacitor define a second three-terminal capacitor, in which the second terminal of the third capacitor and the second terminal of the fourth capacitor are the same terminal of the second three-terminal capacitor.

10. The circuit of claim 1, wherein the packaged IC includes a power converter circuit configured to convert a voltage at the input voltage terminal to an output voltage at an output terminal of the packaged IC.

11. The circuit of claim 10, wherein the first side of the packaged IC includes a first sense terminal and a second sense terminal, one side of the packaged IC includes an output voltage terminal and a third ground terminal, and the circuit further comprises:
a capacitor having first and second capacitor terminals, in which the first capacitor terminal is coupled to the output voltage terminal, the second capacitor terminal is coupled to the third ground terminal; and
a load having first and second load inputs, in which the first load input is coupled to the first capacitor terminal, and the second load input is coupled to the second capacitor terminal, the first sense terminal coupled to the first load input, and the second sense terminal is coupled to the second load input.

12. The circuit of claim 1, wherein the packaged IC comprises:
an output voltage terminal on a respective side of the packaged IC; and
a bridge circuit on substrate within the packaged IC, in which the bridge circuit includes a supply input, a ground input, and an output, the supply input is coupled to the input voltage terminal, and the ground input is coupled to each of the first and second ground terminals; and
an inductor coupled between the output of the bridge circuit and the output voltage terminal.

13. A circuit comprising:
a packaged integrated circuit (IC) including a package body having opposing first and second sides, and a converter circuit on a substrate in the package body,
wherein the first side of the package body includes a first ground terminal, a second ground terminal, and a first input voltage terminal, in which the first input voltage terminal is located substantially equidistant between the first and second ground terminals along the first side of the package body,
wherein the second side of the package body includes a third ground terminal, a fourth ground terminal, and a second input voltage terminal, in which the second input voltage terminal is located between the third and fourth ground terminals along the second side of the package body and the first ground terminal, second ground terminal, and first input voltage terminal are spatially symmetrical relative to the third ground terminals, the fourth ground terminal, and the second input voltage terminal, respectively, and
wherein the converter circuit has first and second converter inputs and a converter output, in which the first converter input is coupled to the first and second input voltage terminals, the second converter input is coupled to at least one of the first, second, third, or fourth ground terminals, and the converter output is coupled to an output terminal along one side of the package body.

14. The circuit of claim 13, wherein the first side of the package body includes a first sense terminal and a second sense terminal, and the circuit further comprises:
a capacitor having first and second capacitor terminals, in which the first capacitor terminal is coupled to the output terminal, the second capacitor terminal is coupled to a respective ground terminal of the package body; and
a load having first and second load inputs, in which the first load input is coupled to the first capacitor terminal, and the second load input is coupled to the second capacitor terminal, the first sense terminal coupled to the first load input, and the second sense terminal is coupled to the second load input.

15. The circuit of claim 13, further comprising:
a printed circuit board (PCB ) having a surface, in which the packaged IC is mounted to the surface of the PCB, the PCB comprising:
a first trace having a proximal end coupled to the first ground terminal and extending from the proximal end thereof away from the first side of the package body;
a second trace having a proximal end coupled to the second ground terminal and extending from the proximal end thereof away from the first side of the package body;
a third trace having a proximal end coupled to the third ground terminal and extending from the proximal end thereof away from the second side of the package body;
a fourth trace having a proximal end coupled to the fourth ground terminal and extending from the proximal end thereof away from the second side of the package body;
a fifth trace having a proximal end coupled to the first input voltage terminal and extending from the proximal end thereof away from the first side of the package body; and
a sixth trace having a proximal end coupled to the second input voltage terminal and extending from the proximal end thereof away from the second side of the package body,
wherein at least a proximal end portion of the fifth trace extends longitudinally between respective proximal end portions of the first trace and the second trace, and
wherein at least a proximal end portion of the sixth trace extends longitudinally between respective proximal end portions of the third trace and the fourth trace.

16. The circuit of claim 15, further comprising
a first capacitor having first and second terminals, in which the first terminal of the first capacitor is coupled to the proximal end portion of the first trace, and the second terminal of the first capacitor is coupled to the proximal end portion of the fifth trace;
a second capacitor having first and second terminals, in which the first terminal of the second capacitor is coupled to the proximal end portion of the second trace, and the second terminal of the second capacitor is coupled to the proximal end portion of the fifth trace;
a third capacitor having first and second terminals, in which the first terminal of the third capacitor is coupled to the proximal end portion of the third trace and the second terminal of the third capacitor is coupled to the proximal end portion of the sixth trace; and
a fourth capacitor having first and second terminals, in which the first terminal of the fourth capacitor is coupled to the proximal end portion of the fourth trace and the second terminal of the fourth capacitor is coupled to the proximal end portion of the sixth trace.

17. The circuit of claim 16, wherein:
the package body has opposing third and fourth sides that extend between the first and second sides,
the package body has a first axis extending through the first and second sides and through the fifth and sixth traces,
the package body has a second axis extending through the third and fourth sides at an intermediate location between the first and second sides, in which the first axis and the second axis are orthogonal with respect to each other, and
the first and second capacitors and the third and fourth capacitors are arranged on the PCB symmetrically with respect to the first axis and the second axis.

18. The circuit of claim 17, wherein:
the first and second capacitors define a first three-terminal capacitor, in which the second terminal of the first capacitor and the second terminal of the second capacitor are the same terminal of the first three-terminal capacitor, and
the third and fourth capacitors define a second three-terminal capacitor, in which the second terminal of the third capacitor and the second terminal of the fourth capacitor are the same terminal of the second three-terminal capacitor.

19. A power converter circuit, comprising:
a packaged integrated circuit (IC) comprising:
a package body having opposing first and second sides;
a first ground terminal, a second ground terminal, and a first input voltage terminal along the first side of the package body, in which the first input voltage terminal is located substantially equidistant between the first and second ground terminals;
a third ground terminal, a fourth ground terminal, and a second input voltage terminal along the second side of the package body, in which the second input voltage terminal is located substantially equidistant between the third and fourth ground terminals, and first input voltage terminal are spatially symmetrical relative to the third ground terminals, the fourth ground terminal, and the second input voltage terminal, respectively; and
a bridge circuit on a substrate in the packaged IC, in which the bridge circuit includes a first supply input, a ground input, and an output, the first supply input is coupled to the first and second input voltage terminals, the ground input is coupled to at least one of the first, second, third, or fourth ground terminals, and the output of the bridge circuit is coupled to an output terminal of the packaged IC along a respective side of the package body;
a first capacitor having first and second terminals, in which the first terminal of the first capacitor is coupled to the first ground terminal and the second terminal of the first capacitor is coupled to the first input voltage terminal;
a second capacitor having first and second terminals, in which the first terminal of the second capacitor is coupled to the second ground terminal and the second terminal of the second capacitor is coupled to the first input voltage terminal;
a third capacitor having first and second terminals, in which the first terminal of the third capacitor is coupled to the third ground terminal and the second terminal of the third capacitor is coupled to the second input voltage terminal; and
a fourth capacitor having first and second terminals, in which the first terminal of the fourth capacitor is coupled to the fourth ground terminal and the second terminal of the fourth capacitor is coupled to the second input voltage terminal.

20. The power converter circuit of claim 19, further comprising:
a printed circuit board (PCB ) having a surface, in which the packaged IC is mounted to the surface of the PCB, the PCB comprising:
a first trace having a proximal end coupled to the first ground terminal and extending from the proximal end thereof away from the packaged IC;
a second trace having a proximal end coupled to the second ground terminal and extending from the proximal end thereof away from the packaged IC;
a third trace having a proximal end coupled to the first input voltage terminal and extending from the proximal end thereof away from the first side of the package body, in which the first terminal of the first capacitor is coupled to a proximal end portion of the first trace, the second terminal of the first capacitor is coupled to a proximal end portion of the third trace, the first terminal of the second capacitor is coupled to a proximal end portion of the second trace, and the second terminal of the second capacitor is coupled to the proximal end portion of the third trace;
a fourth trace having a proximal end coupled to the third ground terminal and extending from the proximal end thereof away from the packaged IC;
a fifth trace having a proximal end coupled to the fourth ground terminal and extending from the proximal end thereof away from the packaged IC; and
a sixth trace having a proximal end coupled to the second input voltage terminal and extending from the proximal end thereof away from the second side of the package body, in which the first terminal of the third capacitor is coupled to a proximal end portion of the fourth trace, the second terminal of the third capacitor is coupled to a proximal end portion of the sixth trace, and the first terminal of the fourth capacitor is coupled to a proximal end portion of the fifth trace, and the second terminal of the fourth capacitor is coupled to the proximal end portion of the sixth trace.

21. The power converter circuit of claim 19, wherein:
the package body has opposing third and fourth sides that extend between the first and second sides,
the package body has a first axis extending through the first and second sides and through the third and sixth traces,
the IC package has a second axis extending through the third and fourth sides at an intermediate location between the first and second sides,
the first axis and the second axis are orthogonal with respect to each other, and
the first and second capacitors and the third and fourth capacitors are arranged symmetrically with respect to the first axis and the second axis.

22. The power converter circuit of claim 19, wherein:
the first and second capacitors define a first three-terminal capacitor, in which the second terminal of the first capacitor and the second terminal of the second capacitor are the same terminal of the first three-terminal capacitor, and
the third and fourth capacitors define a second three-terminal capacitor, in which the second terminal of the third capacitor and the second terminal of the fourth capacitor are the same terminal of the second three-terminal capacitor.

23. The power converter circuit of claim 19, wherein the first side of the package body includes a first sense terminal and a second sense terminal, and the power converter circuit further comprises:
a fifth capacitor having first and second terminals, in which the first terminal of the fifth capacitor is coupled to the output terminal, the second terminal of the fifth capacitor is coupled to a respective ground terminal of the package body; and
a load having a first load input and a second load input, in which the first load input is coupled to the first terminal of the fifth capacitor, and the second load input is coupled to the second terminal of the fifth capacitor, the first sense terminal coupled to the first load input, and the second sense terminal is coupled to the second load input.
